(19) United States
(12) Patent Application Publication
(10) Pub. No.: US 2024/0138273 A1
(43) Pub. Date: Apr. 25, 2024

(54) RESISTIVE MEMORY DEVICE AND MANUFACTURING METHOD

(71) Applicant: COMMISSARIAT A L'ENERGIE ATOMIQUE ET AUX ENERGIES ALTERNATIVES, Paris (FR)

(72) Inventors: Christelle CHARPIN-NICOLLE, Grenoble Cedex 09 (FR); Serge BLONKOWSKI, Grenoble Cedex 09 (FR); Rémy GASSILLOUD, Grenoble Cedex 09 (FR); Thomas MAGIS, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/493,921

(22) Filed: Oct. 24, 2023

(30) Foreign Application Priority Data
Oct. 24, 2022 (FR) 22 11046

(51) Int. Cl. H10N 70/00; H10B 63/00; H10N 70/20

(52) U.S. Cl. CPC H10N 70/828; H10B 63/30; H10N 70/063; H10N 70/24; H10N 70/826; H10N 70/841

(57) ABSTRACT

A resistive memory device including at least one first electrode based on a first metal and a second electrode based on a second metal, and a memory element in the form of a metal filament based on a third metal and inserted between the first and second electrodes, the memory element having a filament cross-section strictly smaller than the electrode cross-sections, wherein the third metal has a chemical composition, different from those of the first and second metals giving it an etching speed greater than those of the first and second metals, preferably such that the selectivity at the etching is greater than or equal to 3:1, vis-á-vis the first and second metals. A method for manufacturing such a device is also disclosed.

### TECHNICAL FIELD

The present invention generally relates to a resistive memory device, and more specifically, a non-volatile resistive memory device and its manufacturing method.

### PRIOR ART

Resistive memories of the RRAM- or ReRAM-type (Resistive Random Access Memories) are currently developed for non-volatile applications, with the aim of replacing Flash-type memories. They have, in particular, the advantage of being able to be integrated in interconnecting lines at the BEOL (Back-End Of Line) level of CMOS (Complementary Metal-Oxide-Semiconductor) transistor-based technology. RRAM resistive memories are devices comprising, in particular, a variable resistance element, called memory element, disposed between two electrodes. The electric resistance of this memory element can be modified by writing and deleting operations. These writing and deleting operations make it possible to make the RRAM resistive memory device pass from a Low Resistive State (LRS) to a High Resistive State (HRS), and vice versa.

According to the nature of the memory element, different RRAM categories or sub-categories can be defined. Resistive memories, of which the memory element is with the basis of a phase change material, typically chalcogenide- or perovskite-based, are generally called PCRAM (Phase Change Random Access Memories). In this type of memory, the LRS/HRS passage is done by a phase change activated thermally. Resistive memories of which the memory element is based on a metal oxide are generally called OxRAM (Oxide Resistive Random Access Memories). In this type of memory, the LRS/HRS passage is done by creating a conductive filament through the oxide, by application of a sufficiently high electric voltage. Resistive memories of which the memory element is based on an electrolyte are generally called CBRAM (Conductive-Bridging Random Access Memories). In this type of memory, the LRS/HRS passage is done by creating a metal nanowire coming from a reduction of metal ions in the electrolyte.

Each of these types of memory has specific problems (thermal management, variability of cycle-to-cycle performances, reactivity, etc.) which today constitute a barrier to industrialization.

Recently, other types of RRAM based on the reversible conduction state of a metal nanofilament have been developed.

The document, “Memristive switching of single-component metallic nanowires, S. L. Johnson et al. Nanotechnology 21 (2010) 125204” discloses an architecture comprising a metal memory element inserted between two electrodes, wherein the metal memory element has a geometric constriction of nanometric dimension. Such a metal “nanowire” can be opened (nanogap) and closed, at least partially, by electromigration and by Joule effect. These two effects increase the probability that a metal atom leaves or fills the constriction when the potential difference between the two electrodes increases. In the “On” state, the conduction in the nanowire is limited by the surface of the cross-section of the constriction. In the “Off” state, the conduction is limited by tunnel effect through the nanogap. Conductances in the On state of 60 mS and in the Off state of 30 mS have been obtained for gold nanowires of 100 nm×20 nm cross-section formed by electronic lithography.

This device made in the laboratory and this formation method are difficult to industrialize. The effectiveness of this memory device remains limited.

An aim of the present invention is to overcome at least partially the disadvantages mentioned above.

An aim of the present invention is to propose a resistive memory device comprising a memory element in the form of a metal nanofilament, which can be industrialized and which has an improved effectiveness.

Another aim of the present invention is to propose a method for manufacturing such a resistive memory device.

The other aims, features and advantages of the present invention will appear upon examining the following description and the accompanying drawings. It is understood that other advantages can be incorporated.

### SUMMARY

To achieve this aim, according to an embodiment, a resistive memory device is provided, comprising at least one first electrode based on a first metal and a second electrode based on a second metal, and a memory element in the form of a metal filament based on a third metal and inserted between said first and second electrodes.

The memory element has a filament cross-section, taken in a transverse plane passing between the first and second electrodes, and the first and second electrodes each have an electrode cross-section, taken respectively in a plane passing through said electrode and parallel to the transverse plane.

The filament cross-section is strictly smaller than the electrode cross-sections, and, the filament cross-section has at least one dimension less than or equal to 20 nm.

Advantageously, the third metal has a chemical composition, different from those of the first and second metals, and this chemical composition gives it an etching speed greater than those of the first and second metals. The chemical composition of the third metal is preferably such that the selectivity at the etching is greater than or equal to 2:1, and preferably greater than or equal to 3:1, vis-á-vis the first and second metals.

Thus, the memory element forms a metal geometric constriction called filament below, between the first and second electrodes. The selectivity properties to the etching of the third metal typically make it possible to form the memory element by simple etching, contrary to known solutions, wherein the memory element is formed by e-beam lithography. This makes such a device compatible with an industrial mass production, contrary to known solutions. Indeed, the e-beam lithography used by known solutions induces a very high cost and very high process time, as the filament patterns are generally defined and formed one-by-one. On the contrary, numerous filaments can be formed simultaneously, thanks to the configuration of the resistive memory device and to the properties of the filament according to the present invention. The device according to the present invention can thus be industrialized a lot more than known devices.

According to an aspect, the invention aims for a system comprising the device and a transistor formed in a substrate carrying said device, the transistor being connected to the device by at least one interconnecting level. The transistor is typically configured to control an electric current passage in the memory element, between the first and second electrodes. The first and second electrodes and the memory element can, in particular, form a vertical stack called memory point. This memory point is thus typically interconnected to the transistor via one or more metal and/or interconnecting levels. Such a system comprising a transistor directly integrated with the memory point can be fully industrialized by CMOS technology methods. Such a system further makes it possible to associate the control transistor closest to the memory point. This makes it possible to limit the connection time and the switching voltage of the filament. The delay for controlling the current passing into the filament is reduced. In known systems and devices, the use of external control equipment induces a delay to limit the current passing into the filament. During this delay, the cross-section of the filament can be damaged by excess current (“overshoot”), such that the memory point is no longer operational. The integration of a transistor and of a metal filament comprising a nanometric constriction, within one same system according to an example of an embodiment of the present invention makes it possible to considerably reduce this delay. The operation of the memory device is thus safer and more effective.

According to another aspect of the invention, a method for producing a resistive memory device is provided, comprising:
A deposition of a first layer based on the first metal, on a substrate,
A deposition of a third layer based on the third metal, on the first layer,
A deposition of a second layer based on the second metal, on the third layer, so as to form a stack of the first, third and second layers, in a vertical direction z,
An etching of the stack, in the vertical direction z, so as to form the first and second electrodes,
An over-etching configured to laterally consume, in a horizontal direction of a horizontal plane xy perpendicular to the vertical direction z, the third metal selectively to the first and second metals, so as to form the memory element in the form of a metal filament inserted between said first and second electrodes.

The method makes it possible to thus easily form, at a reduced cost, a resistive memory device comprising a memory element in the form of a metal filament.

The over-etching step makes it possible to only reduce at least one lateral dimension of the memory element, without reducing the lateral dimensions of the first and second electrodes.

The selectivity S to the etching, in this case corresponds to the etching speed difference between the third metal and the first and second electrode metals, during the over-etching. A selectivity S≥2:1 or S≥3:1 makes it possible, de facto, to obtain a greater lateral removal at the filament during the over-etching. The parameters of the over-etching step are, in this case, chosen, in accordance with the selectivity S, so as to enable a lateral removal, such that the filament cross-section, taken in a plane xy, has at least one dimension less than or equal to 20 nm after over-etching.

This makes it possible to obtain an operational metal filament for the subsequent operating phases of the resistive memory device. In particular, the switching of the resistive memory device by Joule effect and/or by electromigration is made possible.

According to an option, the over-etching step can be advantageously carried out in extension and in the continuity of the etching of the stack. This makes it possible to limit the number of total steps of the method. It is not, for example, necessary to provide additional lithography steps.

### BRIEF DESCRIPTION OF THE FIGURES

The aims, objectives, as well as the features and advantages of the invention will best emerge from the detailed description of embodiments of the latter, which are illustrated by the following accompanying drawings, wherein:

FIGS. 1 to 5 schematically illustrate steps of producing a resistive memory device, according to an embodiment of the present invention.

FIG. 6 is an enlargement of the device during manufacturing illustrated in FIG. 5.

FIGS. 7 and 8 schematically illustrate steps of producing a resistive memory device, according to an embodiment of the present invention.

FIG. 9 illustrates a resistive memory device according to an embodiment of the present invention.

The drawings are given as examples, and are not limiting of the invention. They constitute principle schematic representations, intended to facilitate the understanding of the invention, and are not necessarily to the scale of practical applications. In particular, in the principle diagrams, the thicknesses of the different layers and portions, and the dimensions of the patterns are not necessarily representative of reality.

### DETAILED DESCRIPTION

Before starting a detailed review of embodiments of the invention, optional features are stated below, which can optionally be used in association or alternatively:

According to an example, the first and second electrodes and the memory element are stacked in a so-called vertical direction z, on a substrate extending in a so-called horizontal plane xy, and perpendicular to the vertical direction z. This makes it possible to increase the compactness of the device. The integration of such a device within an electronic circuit is improved.

According to an example, the memory element forms a lateral removal vis-á-vis the first and second electrodes in all the directions of the horizontal plane xy, such that said memory element is substantially centered vis-á-vis the first and second electrodes, projecting in the horizontal plane xy. The lateral dimensions of the metal filament are thus substantially constant. The metal filament thus appears at a cylinder of diameter less than or equal to 20 nm in the plane xy. The cross-section of the filament is minimized. This decreases the current and/or the voltage necessary for the switching of the device. According to an example, the filament has, in the transverse plane, a disc-, square- or rectangle-shaped cross-section.

According to an example, the first and second metals are based on a transition metal or on a nitride of said transition metal, and the third metal is based on an alloy of aluminium and of said transition metal, or on another transition metal.

According to an example, the filament cross-section has a dimension L2 less than or equal to 15 nm in the transverse plane, and the electrode cross-sections each have a dimension L1 greater than or equal to 100 nm, in a plane parallel to said transverse plane. Such a geometric constriction makes it possible to increase the current density in the filament. The switching is facilitated.

According to an example, the first and second metals are based on Ti or TiN, and the third metal is based on TixAly, with x, y>0.

According to an example, the device is associated with a transistor formed in a substrate carrying the first and second electrodes and the memory element, the transistor being configured to control an electric current passage in the memory element, between the first and second electrodes. The memory element and the control transistor are thus integrated in one same stack. The memory element is typically integrated in a BEOL level of an electronic circuit and is connected to a transistor of an FEOL level of said circuit, via one or more interconnecting and metal track levels (“metal” levels). The connection length is thus minimized. The limitation delay, equal to the product of the resistance of the connection by the capacity of the connection connecting the filament, is minimized. The switching voltage is thus reduced.

According to an example, the etching of the stack and/or the over-etching are done by plasma based on a chlorinated chemistry. According to another example, the plasma can be based on a fluorinated, brominated or iodinated chemistry.

According to an example, the over-etching corresponds to an extension of the etching step, by application of an etching time, greater than that making it possible to etch the stack in the vertical direction z. The over-etching is thus done in continuity of the etching of the stack, by extending the duration of said etching. This makes it possible to reduce the total duration of the method for forming the filament, by avoiding, for example, a drainage to change the chemistry of the etching plasma. According to an example, the etching and the over-etching are done by plasma based on a chlorinated chemistry.

According to an example, the etching is configured to be anisotropic in the vertical direction z, and the over-etching is configured to be isotropic, such that the memory element forms a lateral removal vis-á-vis the first and second electrodes in all the directions of the horizontal plane xy, said memory element thus being substantially centered vis-á-vis the first and second electrodes, projecting in the horizontal plane xy. According to an example, the bias voltage applied during the etching is a non-zero voltage V1 and the bias voltage applied during the over-etching is a bias voltage V2 strictly less than V1, for example, V2=0V.

According to an example, the first and second metals are chosen based on Hf, Zr, W, Ti, Ta, TaN or TiN, and the third metal is chosen based on TixAly, ZrxAly, HfxAly, TaxAly, WxAly with x, y>0. In particular, in an etching plasma in chlorinated chemistry, the aluminum is etched between two and three times quicker than the transition metal which is associated with it. Therefore, advantageously, this etching selectivity is used to form the metal filament, for example, based on a titanium-aluminum alloy, between the electrodes, for example, based on titanium. According to an option, y≥0.3 will be chosen. The higher the concentration of aluminum is there, the more the selectivity at the etching increases. This makes it possible, for example, to limit the over-etching time. This makes it possible to obtain significant shape factors between the filament and the electrodes.

According to an example, the method further comprises an integration of the stack on a substrate comprising a transistor configured to control an electric current passage in the memory element, between the first and second electrodes, said integration comprising at least the formation of electric connections between said transistor and at least one from among the first and second electrodes. The formation of electric connections typically corresponds to BEOL steps of the methods used in the microelectronics field. They generally succeed at the FEOL steps making it possible to manufacture elementary components, such as transistors. This method for manufacturing a resistive memory device therefore fully falls under a flow of integration methods used in the microelectronics field.

Unless incompatible, it is understood that all of the optional features above can be combined so as to form an embodiment, which is not necessarily illustrated or described. Such an embodiment is clearly not excluded from the invention. The features and advantages of the device according to the invention can be applied, mutatis mutandis, to the features and advantages of the method according to the invention, and vice versa.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer at least partially covers the second layer, by being either directly in contact with it, or by being separated from it by at least one other layer or at least one other element.

A layer can moreover be composed of several sublayers of one same material or of different materials.

By a substrate, a stack, a layer “based on” a material A, this means a substrate, a stack, a layer comprising this material A only or this material A and optionally other materials, for example alloy elements and/or doping elements. Thus, a layer based on titanium means, for example, a Ti layer, or for example, a TiN layer.

By a “metal” or “based on a metal” structure, this means a structure having properties of a metal. Thus, a metal structure, for example, the filament, necessarily comprises at least one purely metal part. The filament can, for example, have a metal core surrounded by a thin metal oxide layer. Only the core is considered as being purely metal. The metal oxide does not have the electric conduction properties of a metal. The filament cannot be fully based on metal oxide. The memory elements of OxRAMs based on metal oxide cannot be assimilated to a metal filament, such as described and illustrated in the scope of the present invention.

By “selective etching vis-á-vis” or “etching having a selectivity vis-á-vis”, this means an etching configured to remove a material A or a layer A vis-á-vis a material B or a layer B, and having an etching speed of the material A greater than the etching speed of the material B. The selectivity is the ratio between the etching speed of the material A over the etching speed of the material B.

In the present patent application, the memory element is equally called “the filament” or “the metal filament”. The resistive memory device is also called “memory point”.

Several embodiments of the invention implementing successive steps of the manufacturing method are described below. Unless explicitly mentioned otherwise, the adjective “successive” does not necessarily imply, even if this is generally preferred, that the steps immediately follow one another, intermediate steps being able to separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be repeated. Thus, the term “step” does not necessarily mean single and inseparable actions over time and in the sequence of phases of the method.

A preferably orthonormal system, comprising the axes x, y, z is represented in the accompanying figures. When one single system is represented on one single set of figures, this system is applied to all the figures of this set.

In the present patent application, the thickness of a layer is taken in a direction normal to the main extension plane of the layer. Thus, a layer typically has a thickness along z. The relative terms “on”, “surmounts”, “under”, “underlying”, “inserted”, refer to positions taken in the direction z.

The terms “vertical”, “vertically”, refer to a direction along z. The terms “horizontal”, “horizontally”, “lateral”, “laterally”, refer to a direction in the plane xy. Unless explicitly mentioned otherwise, the thickness, the height and the depth are measured along z.

An element located “in vertical alignment with” or “to the right” of another element, means that these two elements are both located on one same line, perpendicular to a plane, wherein a lower or upper face of a substrate mainly extends, i.e. on one same line oriented vertically in the figures.

By “industriability”, this means the measurement of the industrializable character.

In the scope of the present invention, by horizontal removal or lateral removal, this means a removal of material from a face substantially perpendicular to the plane xy, in a direction normal to this face. The lateral removal of a layer typically forms a step or an overhang vis-á-vis the other layers below or above, respectively. The lateral removal can be formed on only some of the perimeter of the memory element. The lateral removal can be formed on the entire perimeter of the memory element. In the latter case, along a cross-section, a lateral removal of each side of the memory element is observed, that is two lateral removals (which are, in reality, two parts of the same lateral removal).

In the scope of the present invention, the transverse plane is preferably parallel to the horizontal plane xy. The filament cross-section is measured in the transverse plane. The smallest dimension of the cross-section of the filament is measured in a so-called transverse direction of this transverse plane.

The electrode cross-sections are measured in planes parallel to the transverse plane. The electrode cross-sections are typically measured, along the axis z, at the interface between the filament and the electrode.

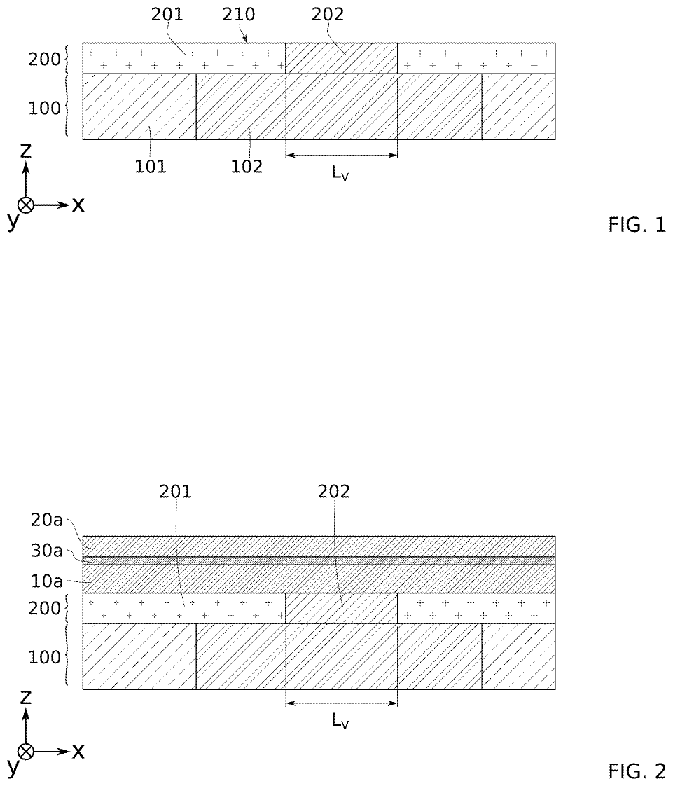

FIGS. 1 to 8 illustrate an embodiment of the resistive memory device and of its manufacturing method according to the invention. In the examples illustrated, the resistive memory device takes the form of a memory point of width L1. This memory point can appear at a vertical cylinder comprising the first and second electrodes and the metal filament. It is typically formed from a stack of layers, by deposition, lithography, etching steps. These different steps are detailed below. Other forms of memory point or of resistive memory device can be fully considered, for example, a cube or a parallelepiped, a cylinder of square or ellipsoidal cross-section. The cross-section can be regular or irregular. Typically, a perfect shape drawn on an etching mask is transferred into the stack with imperfections linked to lithography and etching technologies. According to a principle of the invention, a memory element in the form of a filament based on a metal material, is inserted in the stack of the memory point, between the electrodes, and forms a geometric constriction vis-á-vis the electrodes. The electrode materials and the metal material of the filament are preferably chosen, such that, under the given etching conditions, the etching speed of the metal material of the filament is greater than the etching speed of the electrode materials. This makes it possible to obtain the filament by lateral narrowing of the metal material.

The resistive memory device is typically formed during so-called BEOL end-of-line technological steps. Thus, as illustrated in FIG. 1, a substrate (not illustrated) carrying different metal and via levels is provided. In FIG. 1 of the illustration, only the last metal and via levels are represented. The metal level 100 typically comprises metal lines or tracks 102 isolated from one another by a dielectric material 101, typically SiO₂. The interconnecting level 200 typically comprises through vias 202 isolated from one another by a dielectric material 201, typically SiN, or other dielectric materials, such as SiC or so-called “Ultra Low K” materials. The vias 202 typically have a dimension by width Lv along x. The width Lv of the vias 202 is typically comprised between a few tens of nanometers and a few hundred nanometers, for example between 5 nm and 1000 nm, preferably between 10 nm and 500 nm. A face 210 of the last level 200 is exposed.

As illustrated in FIG. 2, a stack of layers 10a, 30a, 20a is formed on the exposed face 210. In this example, a first layer 10a, intended to form the lower electrode, is deposited directly in contact with the face 210. This layer 10a is, in this case, fully formed of a first metal. It is preferably based on a transition metal, for example, Ti or TiN, or also on TaN. Zr, Hf, Ta, W can also be used.

A thin metal layer 30a is then deposited above the first layer 10a. This layer 30a is, in this case, fully formed of a third metal, different from the first metal. This layer 30a is preferably based on an alloy of aluminum and of a transition metal, for example, TixAly-based, with x, y>0, for example TiAlo 3. The aluminum percentage of the layer 30a can vary, for example between 1% and 99%. Zr, Hf, Ta, W can be used in replacement for Ti in the aluminum alloy of the layer 30a. The layer 30a is intended to form the memory element.

A second electrode layer 20a, intended to form the upper electrode, is then formed on the metal layer 30a. This second layer 20a is, in this case, fully formed of a second metal, different from the third metal. It is preferably based on a transition metal, for example, Ti or TiN, or also, TaN. Zr, Hf, Ta, W can also be used. The second electrode 20 is preferably based on the same metal as the first layer 10a.

The metal layers 10a, 30a, 20a are preferably directly in contact with one another, as illustrated in FIG. 2. The thickness of the first layer 10a is preferably between 5 nm and 200 nm. The thickness of the layer 30a is preferably between 5 nm and 100 nm. The thickness of the second layer 20a is preferably between 5 nm and 200 nm.

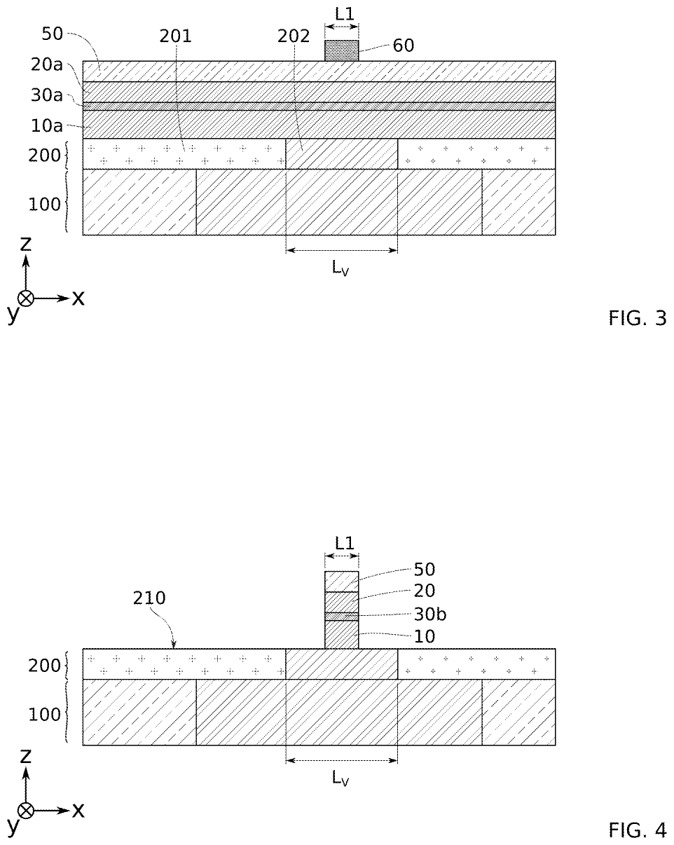

FIG. 3 illustrates a lithography step carried out prior to the etching of the stack of electrode layers and of the metal memory element. A resin pattern 60 is formed in vertical alignment with the via 202, for example such that said pattern 60 is centered vis-á-vis the via 202, projecting into the plane xy. This pattern 60 defines the shape and the dimensions, projecting into the plane xy, from the desired memory point. It typically has at least one dimension by width L1 greater than or equal to 50 nm, preferably greater than or equal to 100 nm. A hard mask layer 50, for example, SiN- or SiO₂-based, can be deposited on the upper electrode 20 before formation of the pattern 60. In a known manner, such an optional layer 50 makes it possible to transfer, more accurately, the shape and the dimensions of the pattern 60 in the stack of underlying layers 20, 30, 10, during the following etching. This layer 50 also makes it possible to protect the stack during certain steps, in particular, during the step of removing the resin, commonly called “stripping”.

FIG. 4 illustrates the etching of the stack of layers 20a, 30a, 10a, respectively. In this example, the hard mask 50 of width L1 is represented. Conventionally, the layer 50 is first etched anisotropically along z. The resin pattern 60 is thus removed. Then, the assembly of the stack of the layers 20a, 30a, 10a is etched anisotropically along z.

The latter etching is done, preferably by plasma in chlorinated chemistry. This makes it possible to obtain a stack of width L1, comprising, from the face 210, a first electrode 10, for example, TiN-based, a metal layer 30b, for example, TixAly-based, a second electrode 20, for example, TiN-based. Stopping the etching is done, preferably on the exposed via 202, at the face 210. This stopping of etching is not necessarily selective, in particular because the via(s) 202 can be made of TiN.

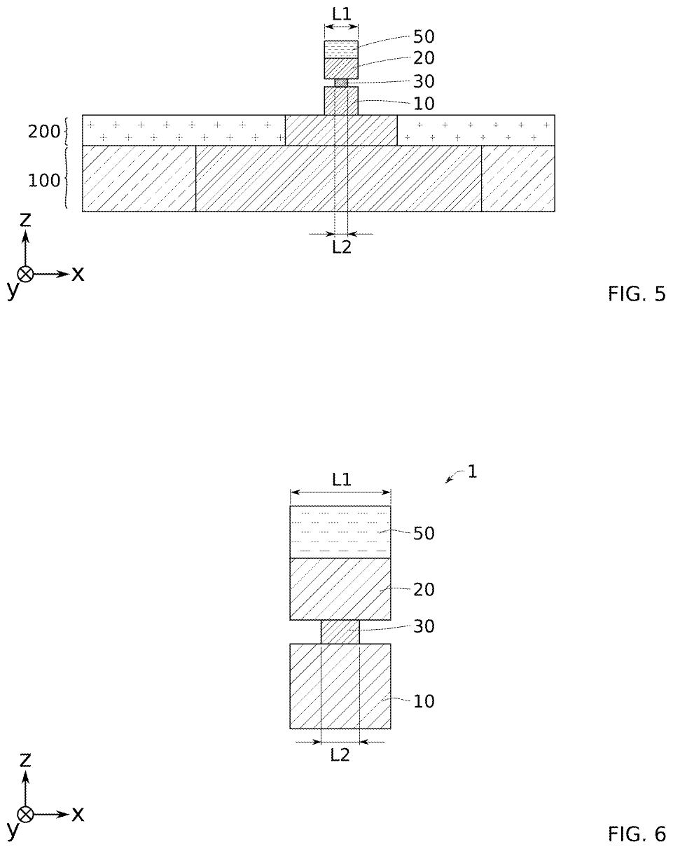

FIG. 5 illustrates an over-etching step making it possible to reduce, by width, the metal layer 30b only, by substantially preserving the dimension L1 for the other layers 10, 20 of the stack. During the over-etching, the TixAly-based layer 30b is etched laterally, along x as a cross-section in FIG. 5, until obtaining a metal “filament” 30 of dimension L2. The over-etching is done, typically on either side of the flanks of the stack, such that the metal filament 30 remains roughly centered vis-á-vis the first and second electrodes 10, 20. A lateral removal is thus obtained from each side of the filament 30. This removal can thus be symmetrical vis-á-vis the axis z passing through the center of the stack. According to another option, the lateral removal can be formed asymmetrically, the over-etching being able to be impacted by the pattern density on either side of the memory point.

The over-etching is configured such that the dimension L2 of the filament 30 is less than or equal to 20 nm, and preferably less than or equal to 15 nm, for example, of around 10 nm along x, and/or along y. The duration of the over-etching can, in particular, be adjusted according to the desired lateral removal. According to an example, the parameters of the over-etching are substantially the same as those of the etching. The over-etching thus corresponds to an increase of the etching duration. According to another option, the parameters of the over-etching are modified, typically such that the isotropy of the over-etching is increased. According to an example, the bias voltage applied to the plasma is decreased, even annulled. This increases the isotropic character of the plasma. According to an example, the pressure and/or the volume flow rates of the gases of the plasma are increased. This increases the isotropic character of the plasma.

FIG. 6 schematically illustrates the memory point 1 obtained from the over-etching. The metal filament 30 is inserted between the electrodes 10, 20, with an aspect ratio L1/L2≥5.

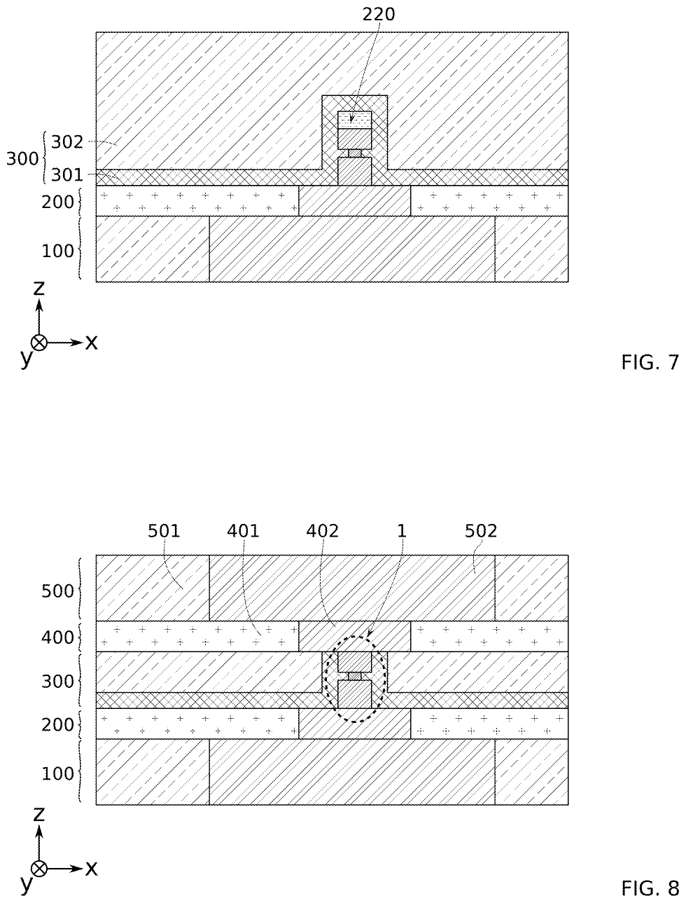

As illustrated in FIG. 7, the memory point is then encapsulated by one or more dielectric layers, for example by a first SiN layer 301, then by a second SiO 2 layer 302. The first SiN layer 301 has, for example, a thickness of 30 nm. It is consistently deposited on the memory point. The SiO₂ layer 302 can have a thickness of 300 nm. These layers 301, 302 form a dielectric encapsulation level 300 around the memory point. According to an alternative option, this dielectric encapsulation level 300 can be formed by one single layer, for example by an SiO₂- or SiN-based layer.

After deposition of the dielectric layer(s) 301, 302, a planarization step, for example by chemical mechanical polishing, is carried out so as to expose an upper face 220 of the upper electrode 20.

As illustrated in FIG. 8, the via 400 and metal 500 levels are then formed after the planarization step. This makes it possible to form a metal contact on the memory point 1. The interconnecting level 400 typically comprises through vias 402 isolated from one another by a dielectric material 401, typically SiN. The via(s) 402 is/are preferably centered vis-á-vis the upper electrode 20 of the memory point 1. In FIG. 8, the vias of the levels 200, 400 are represented wider than the dimension L1 of the memory point 1. According to another option, the vias of one or more levels 200, 400 can have a dimension along x and/or along y less than the dimension L1 of the memory point 1. The metal level 500 typically comprises metal lines 502 isolated from one another by a dielectric material 501, typically SiO₂.

The device 1 illustrated in FIG. 8 is thus fully operational. The top contact formed by the via 402 and the metal line 502, and the bottom contact formed by the via 202 and the metal line 102, can be formed conventionally, without particular dimensional constraints. The device 1 can thus be produced by standard technological microelectronic steps. The introduction of a metal layer between the electrodes of the memory point, as a stack, coupled to the production of a selective over-etching of this inserted metal layer, makes it possible to advantageously form the metal filament of the memory point.

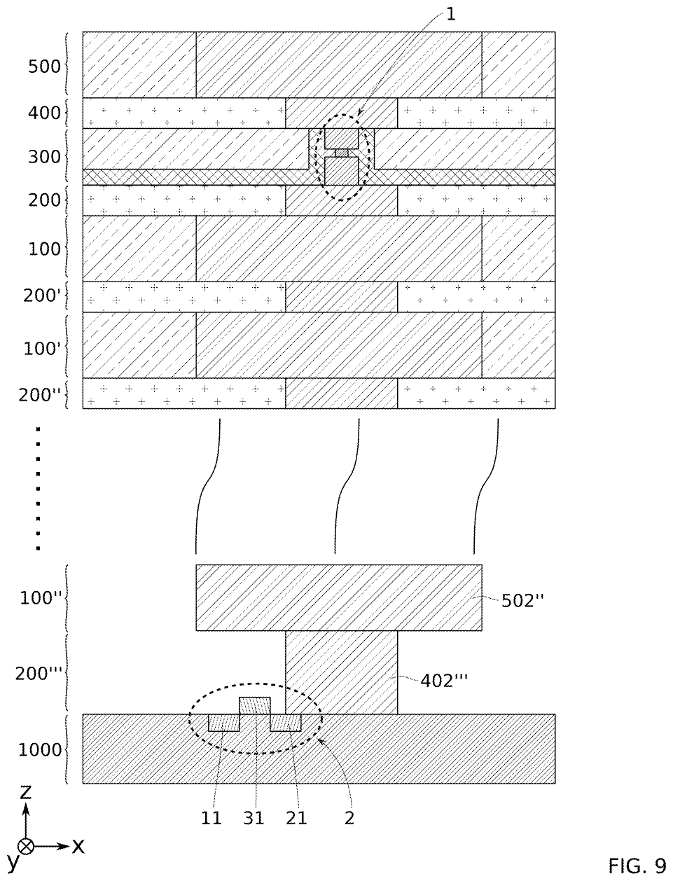

FIG. 9 illustrates a preferred embodiment of the device and of its manufacturing method.

In this example, the resistive memory device 1 is connected to a control transistor 2 via one or more metal 100, 100′, 100″ and/or interconnecting 200, 200′, 200″, 200′″ levels. The control transistor 2 can be a field effect transistor comprising a gate 31 and a source and drain 11, 21. The connection between the memory device 1 and the transistor 2 is done typically in series, for example, by way of a via 402″′connected to the drain 21 of the transistor 2, and of a first metal level 502″. The control transistor 2 is configured to control a passage of the current in the metal filament of the device 1.

The resistive memory device 1 is advantageously integrated in the stack of the BEOL levels and connected to the transistor 2 of the FEOL level. Such an integration makes it possible to limit the voltage necessary for the switching of the resistive memory device 1. Controlling the device is optimized. The reliability of the resistive memory device 1 is improved. The system comprising the resistive memory device 1 and the transistor 2 connected by at least one interconnecting and/or metal level can be directly achieved in an integrated circuit. The integration of the system is improved.

In this example, the resistive memory device 1 is formed between interconnecting levels 200, 400. Other metal 500 and/or interconnecting levels can typically surmount the device 1.

Numerous stack configurations including a resistive memory device 1 and a transistor 2 are possible. These variants are not necessarily illustrated, but can be easily deduced by combining the features of the embodiments described.

The invention is not limited to the embodiments described above.

1. A resistive memory device comprising at least one first electrode based on a first metal and a second electrode based on a second metal, and a memory element in the form of a metal filament based on a third metal and inserted between said first and second electrodes, said memory element having a filament cross-section, taken in a so called transverse plane passing between the first and second electrodes, and said first and second electrodes each have an electrode cross-section, taken respectively in a plane passing through said electrode and parallel to the transverse plane, such that the filament cross-section is strictly smaller than the electrode cross-sections and such that the filament cross-section has at least one dimension L2 less than or equal to 20 nm, wherein the third metal has a chemical composition different from those of the first and second metals giving it an etching speed greater than those of the first and second metals, such that the selectivity at the etching is greater than or equal to 2:1, vis-à-vis the first and second metals.

2. The device according to claim 1, wherein the first and second electrodes and the memory element are stacked in a vertical direction (z), on a substrate extending in a horizontal plane (xy) and perpendicular to the vertical direction (z).

3. The device according to claim 2, wherein the memory element forms a lateral removal vis-à-vis the first and second electrodes in all the directions of the horizontal plane (xy), such that said memory element is substantially centered vis-á-vis the first and second electrodes, projecting in the horizontal plane (xy).

4. The device according to claim 1, wherein the first and second metals are based on a transition metal or a nitride of said transition metal, and the third metal is based on an alloy of aluminum and of said transition metal, or on another transition metal.

5. The device according to claim 1, wherein the filament cross-section has a dimension L2 less than or equal to 15 nm in the transverse plane, and wherein the electrode cross-sections each have a dimension L1 greater than or equal to 100 nm, in a plane parallel to said transverse plane.

6. The device according to claim 1, wherein the first and second metals are based on Ti or TiN, and the third metal is based on TixAly, with x, y>0.

7. A system comprising a device according to claim 1, and a transistor formed in a substrate carrying said device, the transistor being connected to the device by at least one interconnecting level, the transistor further being configured to control an electric current passage in the memory element, between the first and second electrodes.

8. A method for producing a resistive memory device according to claim 1, comprising:
a deposition of a first layer based on the first metal, on a substrate,
a deposition of a third layer based on the third metal, on the first layer,
a deposition of a second layer based on the second metal, on the third layer, so as to form a stack of the first, third and second layers, in a vertical direction (z),
an etching of the stack, in the vertical direction (z), so as to form the first and second electrodes,
an over-etching configured to laterally consume, in a horizontal direction of a horizontal plane (xy) perpendicular to the vertical direction (z), the third metal selectively over the first and second metals, so as to form the memory element in the form of a metal filament inserted between said first and second electrodes.

9. The method according to claim 8, wherein the over-etching is done by plasma based on a chlorinated chemistry.

10. The method according to claim 8, wherein the over-etching corresponds to an extension of the etching step, by application of an etching time greater than that making it possible to etch the stack in the vertical direction (z).

11. The method according to claim 8, wherein the etching is configured to be anisotropic in the vertical direction (z), and the over-etching is configured to be isotropic, such that the memory element forms a lateral removal vis-à-vis the first and second electrodes in all the directions of the horizontal plane (xy), said memory element thus being substantially centered vis-á-vis the first and second electrodes, projecting in the horizontal plane (xy).

12. The method according to claim 8, wherein the first and second metals are chosen based on Hf, Zr W, Ti, Ta, TaN or TiN, and the third metal is chosen based on TixAly, ZrxAly, HfxAly, TaxAly, WxAly with x, y>0.

13. The method according to claim 8, said method further comprising an integration of the stack on a substrate comprising a transistor configured to control an electric current passage in the memory element, between the first and second electrodes, said integration comprising at least the formation of electric connections between said transistor and at least one from among the first and second electrodes.
